(19) United States
(12) Patent Application Publication
(10) Pub. No.: US 2012/0224323 A1
(43) Pub. Date: Sep. 6, 2012

(54) TABLET PC SUPPLEMENTARY DEVICE

(76) Inventor: Shang-Wen YANG, New Taipei City (TW)

(21) Appl. No.: 13/039,929

(22) Filed: Mar. 3, 2011

(51) Int. Cl. H05K 7/00

(52) U.S. Cl. 361/679.55

(57) ABSTRACT

A tablet PC supplementary device includes a base frame unit having multiple locating grooves spaced on a flat base panel thereof, and a holder frame unit, which includes a flat holder panel defining therein an accommodation open chamber for accommodating a tablet PC, a retractable connecting device pivotally connecting the flat holder panel to the base frame unit and pivotally and rotatably connecting the flat holder panel to the connecting device for enabling the flat holder panel to be adjusted horizontally and vertically to hold the loaded tablet PC in any desired tilted operating position or to protect the loaded tablet PC in a well-protected position convenient for carrying and storage.

### BACKGROUND OF THE INVENTION

1. Field of the Invention

The present invention relates to a device for holding a tablet PC and more particularly, to a tablet PC supplementary device, which can be conveniently adjusted to hold the loaded tablet PC in any desired tilted operating position or to receive the loaded tablet PC in a well-protected condition convenient for carrying and storage.

2. Description of the Related Art

Following fast development of computer electronic technology, many versatile electronic products have been created, and have appeared on the market. These versatile electronic products bring convenience to people, and help people to handle different jobs and processing data rapidly and efficiently. Nowadays, mobile electronic products have light, thin, short and small characteristics. Conventionally, a computer system consists of a host, a monitor, a keyboard, a mouse, a printer and or many other peripheral apparatuses. Installation of a conventional computer system is complicated. For the advantage of high mobility, notebook computer may be used instead of a desk computer. A notebook computer generally comprises a base member carrying an operating circuit assembly and a keyboard, and a cover member carrying a display screen and hinged to the base member. When using a notebook computer, the user can open the cover member from the base member to a tilted operating position (about 90° angle relative to the base member. When compared to a desk computer, a notebook computer has the advantage of high mobility. However, a notebook still has a certain dimension and a certain weight (about 1˜2 kgs). Carrying a notebook computer still requires some effort. To enhance mobility and operating convenience, tablet personal computer (such as i-pad) is created. A tablet PC is equipped with a touchscreen as a primary input device and designed to be operated and owned by an individual. Further, a tablet PC has a wireless adapter for Internet and local network connection. However, conventional tablet personal computers are still not satisfactory in function and have drawbacks as follows:
1. When using a tablet PC, the touchscreen can simply be kept in horizontal for operation. During operation, the user must lower the head to watch the screen. After a long use, the user's neck and shoulders will feel uncomfortable. Further, the tablet PC may easily be forced to displace on the supporting surface during operation.
2. The touchscreen of a tablet PC is exposed to the outside. When carrying or storing a tablet PC, the touchscreen of the tablet PC may be scratched or damaged accidentally, affecting the functioning of the tablet PC and shortening its lifespan.

Therefore, it is desirable to provide a supplementary device for use with a tablet PC that eliminates the aforesaid problems.

### SUMMARY OF THE INVENTION

The present invention has been accomplished under the circumstances in view. It is one object of the present invention to provide a tablet PC supplementary device, which can be conveniently adjusted to hold the loaded tablet PC in any desired tilted operating position or to receive the loaded tablet PC in a well-protected condition convenient for carrying and storage.

To achieve this and other objects of the present invention, a tablet PC supplementary device comprises a base frame unit and a holder frame unit. The base frame unit comprises a flat base panel having a springy hook flange located on the front side thereof, a coupling structure located on the rear side thereof and a plurality of locating grooves spaced on a top wall thereof between the springy hook flange and the coupling structure. The holder frame unit comprises a flat holder panel defining therein an accommodation open chamber for accommodating a tablet PC, a retractable connecting device pivotally connecting the flat holder panel to the coupling structure of the base frame unit and pivotally and rotatably connecting the flat holder panel to the connecting device, and positioning blocks located on one side of the flat holder panel for selectively positioning in the locating grooves to support the flat holder panel on the flat base panel in a tilted position. When the holder frame unit is closed on the base frame unit, the flat holder base panel is forced into engagement with the springy hook flange and firmly held in the close position to well protect the loaded tablet PC against scratching.

Further, the connection device comprises a connection plate member pivotally connected to the coupling structure of the flat base panel and defining therein a sliding way, a sliding plate member coupled to and movable in and out of the sliding way of the connection plate member, and a swivel connector pivotally connected to one end of the sliding plate member outside the connection plate member, a hollow shaft fixedly located on the flat holder panel, and a retaining member fastened to the swivel connector to rotatably secure the swivel connector to the hollow shaft.

The holder frame unit further comprises two sleeves fixedly located on the flat holder panel in a parallel manner, each sleeve having an opening on one end thereof, and a handle coupled to and slidably movable in and out of the opening of each sleeve.

### BRIEF DESCRIPTION OF THE DRAWINGS

Other and further advantages and features of the present invention will be fully understood by reference to the following specification in conjunction with the accompanying drawings.

FIG. 1 is an elevational view of a tablet PC supplementary device in accordance with the present invention.

FIG. 2 is an exploded view of the tablet PC supplementary device in accordance with the present invention.

FIG. 3 corresponds to FIG. 2 when viewed from another angle.

FIG. 4 is a sectional side view of the tablet PC supplementary device in accordance with the present invention.

FIG. 5 is a schematic side view of the present invention, illustrating the base frame unit opened from the holder frame unit.

FIG. 6 is a schematic side view of the present invention, illustrating the flat holder panel stopped at the stop members of the flat base panel of the base frame unit in a tilted position in the horizontal operating mode.

FIG. 7 is an oblique front elevational view of FIG. 5.

FIG. 8 is an oblique front elevational view of the present invention, illustrating a tablet PC held in the flat holder panel and set in a tilted position in the vertical operating mode.

FIG. 9 is a schematic sectional side view of FIG. 8.

### DETAILED DESCRIPTION OF THE PREFERRED EMBODIMENT

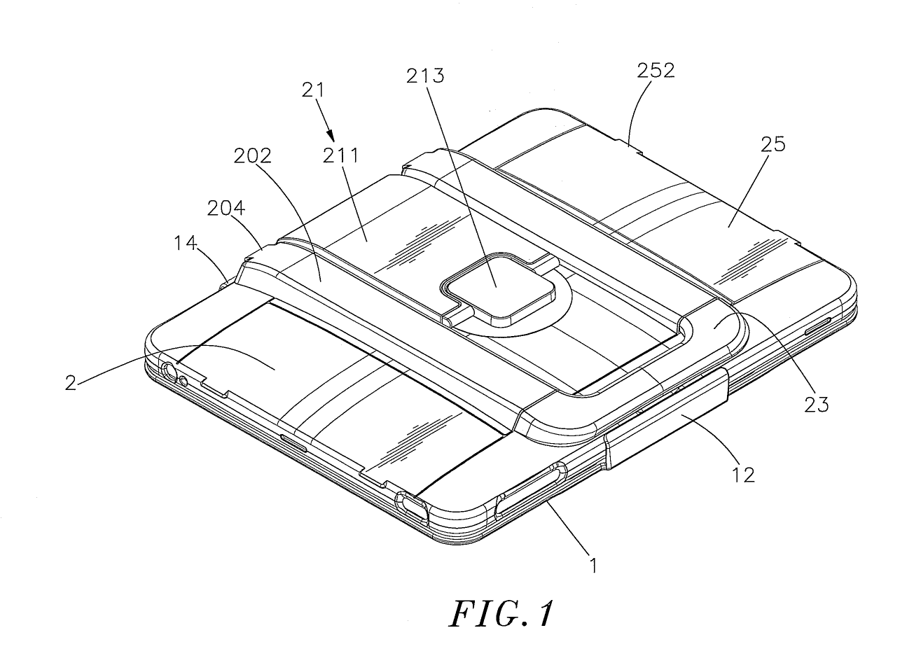

Referring to FIGS. 1˜3, a tablet PC supplementary device in accordance with the present invention is shown comprising a base frame unit 1 and a holder frame unit 2.

The base frame unit 1 comprises a flat base panel 11 having multiple, for example, but not limited to, two rows of locating grooves 110 arranged in parallel onto the top wall thereof, a springy hook flange 12 protruded from a middle part of a front side of the flat base panel 11, two stop members 13 hinged to (a respective recessed area on) the top wall of the flat base panel 11 at two opposite lateral sides relative to the springy hook flange 12 and biasable relative to the flat base panel 11 between a collapsed non-operative position where the stop members 13 are kept in flush with the top wall of the flat base panel 11 and an operative position where the stop members 13 protrude over the top wall of the flat base panel 11 at a predetermined angle, and a coupling structure 14 located on a rear side of the flat base panel 11. The coupling structure 14 defines therein a groove 141 on the middle and two knuckles 140 axially aligned at the two distal ends of the groove 141.

The holder frame unit 2 comprises a flat holder panel 20, a connection device 21, a hollow shaft 22, a handle 23, a packing rim 24 and a side cover 25. The connection device 21 comprises a connection plate member 211, a sliding plate member 212 and a swivel connector 213. The connection plate member 211 is coupled to the coupling structure 14 of the flat base panel 11 of the base frame unit 1, having two rails 2111 arranged in parallel at two opposite lateral sides thereof, a sliding way 2110 defined in between the two rails 2111 and a plurality of positioning grooves 2112 arranged in a line in the sliding way 2110 between the two rails 2111. The sliding plate member 212 is movable in and out of the sliding way 2110 between the two rails 211 of the connection plate member 211, having a springy retaining portion 2121 located on a rear side thereof and selectively engaged in one of the positioning grooves 2112, a U-shaped front coupling arm 2122 located on a front side thereof, and a pivot pin 2122 respectively and inwardly protruded from each of the two distal ends of the U-shaped front coupling arm 2122 and pivotally coupled to a respective pivot hole 2131 on the swivel connector 213. The swivel connector 213 is rotatably coupled to the hollow shaft 22 at the center of the flat holder panel 20 by a retaining member 2132. The flat holder panel 20 has defined in one side thereof an accommodation open chamber 201, two sleeves 202 disposed in the accommodation open chamber 201 at two opposite lateral sides relative to the hollow shaft 22, and two coupling holes 208 disposed adjacent to one side of one sleeve 202. Each sleeve 202 has an opening 203 located on its one end and a positioning block 203 protruded from its other end over one adjacent border edge of the flat holder panel 20, a stop flange 205 extending around the opening 203, and a springy retaining device 206 disposed therein at a far place from the opening 203. The handle 23 is a substantially U-shaped frame bar, having two parallel arms 231 respectively slidably inserted through the openings 203 into the sleeves 202 and a locating end portion 232 located on the distal end of each of the arms 231. The handle 23 is movable in and out of the sleeves 202 between a received position and an extended position. When the handle 23 is in the received position, the locating end portions 232 are forced into friction engagement with the springy retaining devices 206 in the sleeves 202. When the handle 23 is in the extended position, the locating end portions 232 are stopped at the stop flanges 205 in the respective openings 203 of the sleeves 202. Further, an inner covering 207 is fastened to the flat holder panel 20 and covered over the accommodation open chamber 201. The packing rim 24 is configured subject to the configuration of the flat holder panel 20 and packed on the border edge of the flat holder panel 20, having a retaining flange 241 extending along the length thereof at an inner side. The side cover 25 has two coupling portions 251 bilaterally disposed at a front side thereof and respectively pivotally coupled to the coupling holes 208 of the flat holder panel 20, and two locating blocks 252 bilaterally disposed at a rear side thereof.

When assembling the tablet PC supplementary device, the connection plate member 211 of the connection device 21 is attached with its one end to the groove 141 of the coupling structure 14 and pivotally connected between the two knuckles 140 of the coupling structure 14 by a pivot pin 214.

It is to be understood that the coupling arrangement between the connection plate member 211 and the coupling structure 14 is not limited to the aforesaid design. Any of a variety of other hinge designs can be used to pivotally connect the connection plate member 211 and the coupling structure 14 together.

Further, a tablet PC, electronic book, electronic game machine, LCD screen or TV tablet can be accommodated in the accommodation open chamber 201 of the flat holder panel 20 of the holder frame unit 2, and the holder frame unit 2 can be biased relative to the base frame unit 1 and positioned in one of a series of tilted position with the positioning blocks 204 selectively positioned in the locating grooves 110 of the flat base panel 11 (this will be described further).

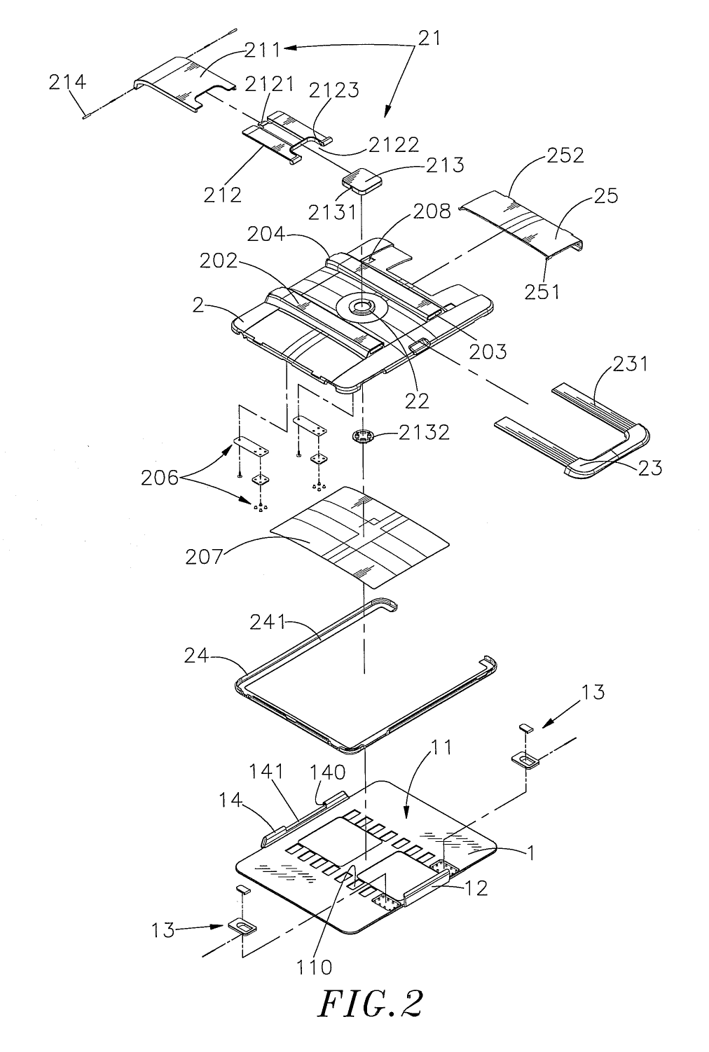

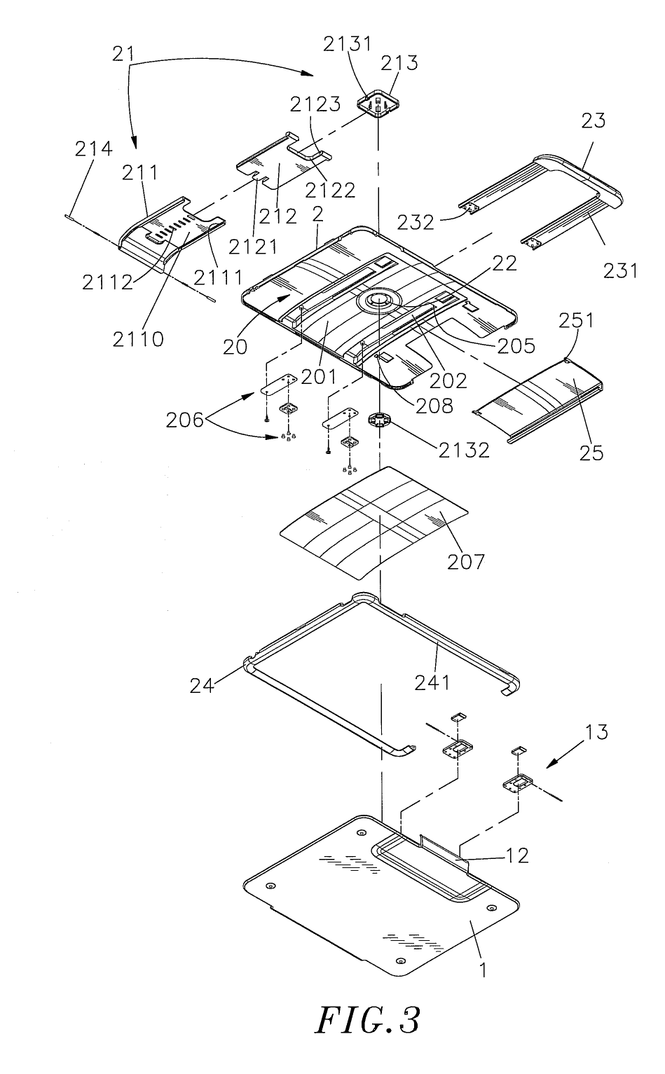

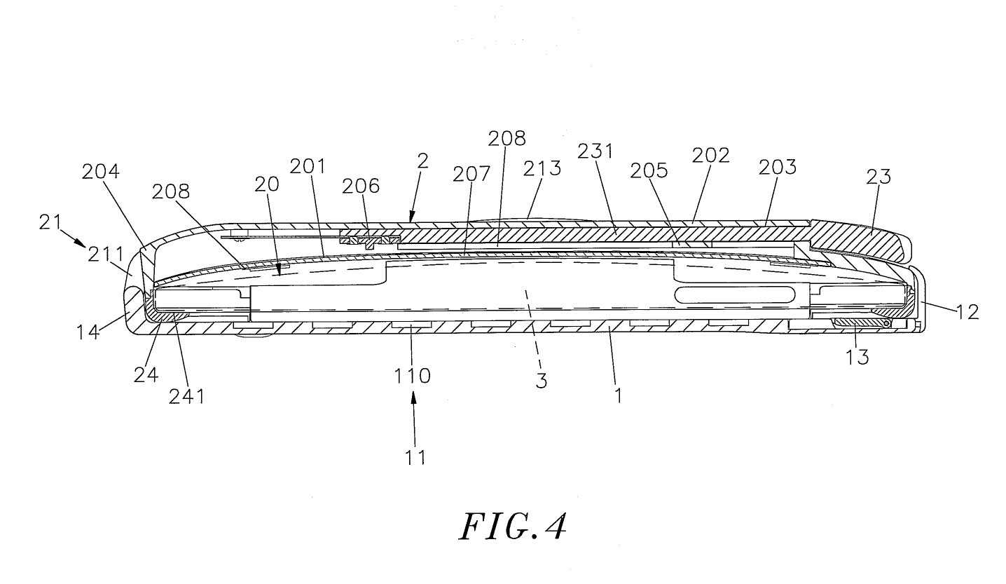

Referring to FIGS. 4˜8 and FIGS. 2 and 3 again, the packing rim 24 packed on the border edge of the flat holder panel 20. During application, a tablet PC 3 can be accommodated in the accommodation open chamber 201 of the flat holder panel 20 of the holder frame unit 2. After insertion of the tablet PC 3 into the accommodation open chamber 201 of the flat holder panel 20, the tablet PC 3 is kept in friction engagement with the retaining flange 241 of the packing rim 24. At this time, the flat holder panel 20 of the holder frame unit 2 can be closed on the base frame unit 1, and thus the tablet PC 3 is firmly received in between the base frame unit 1 and holder frame unit 2 of the tablet PC supplementary device, convenient for carrying and storage, and the surface or screen 31 of the tablet PC 3 is well protected against damage. When the flat holder panel 20 of the holder frame unit 2 is closed on the base frame unit 1, the springy hook flange 12 secures the flat holder panel 20 in the closed position firmly. Further, the tablet PC supplementary device is configured subject to the configuration of the tablet PC 3, having compact and light weight characteristics. Further, the user can pull the handle 23 out of the sleeves 202 for carrying by hand.

Further, the retaining flange 241 of the packing rim 24 has a smooth outer surface. When the user inserts the table PC 3 into the accommodation open chamber 201 of the flat holder panel 20, the tablet PC 3 is forced in friction engagement with the retaining flange 241 of the packing rim 24, and the retaining flange 241 will not damage the surface of the tablet PC 3. Thus, the tablet PC 3 can be held firmly in the accommodation open chamber 201 of the flat holder panel 20.

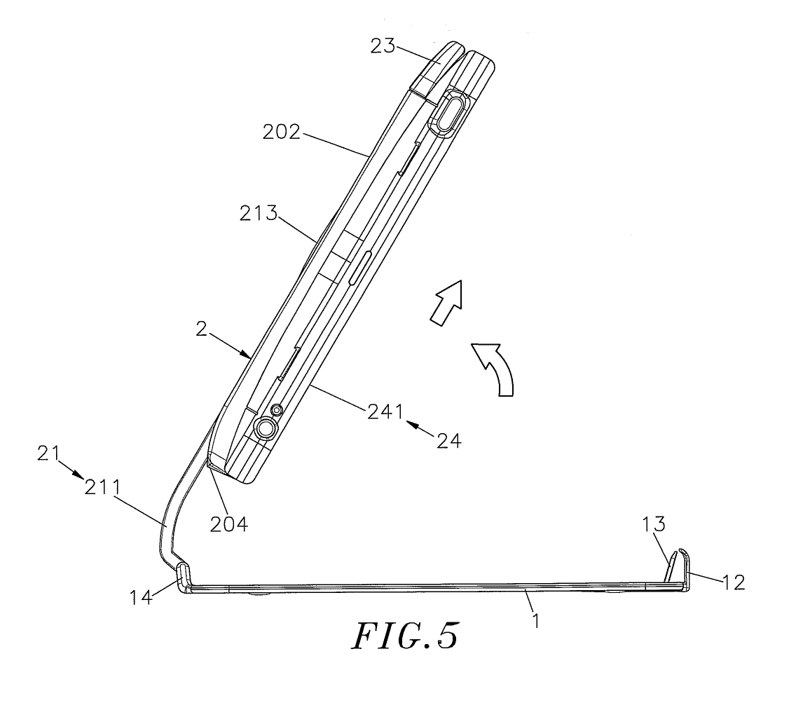

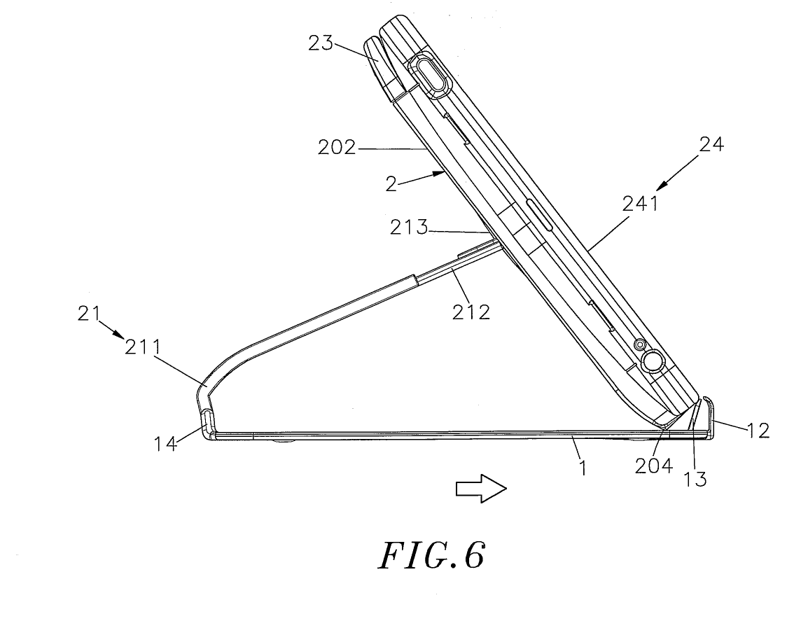

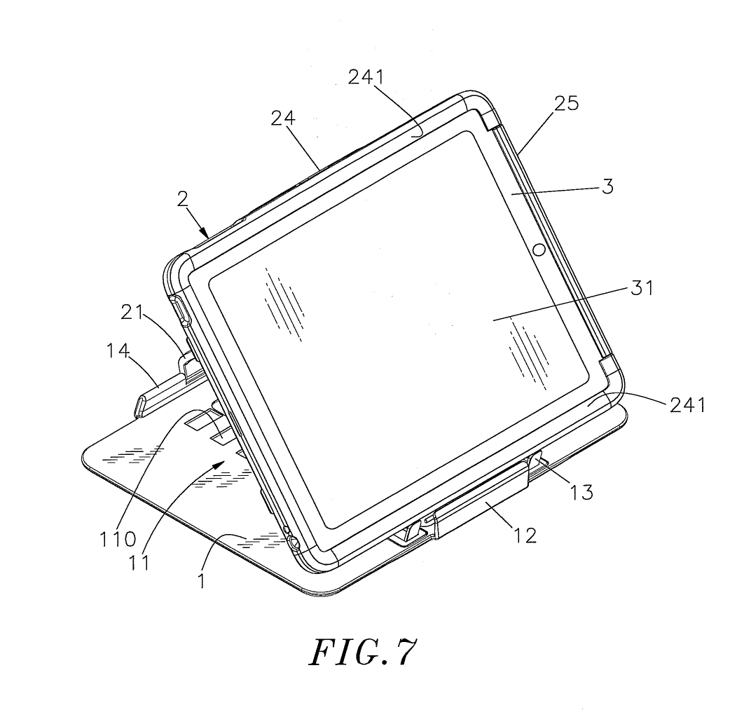

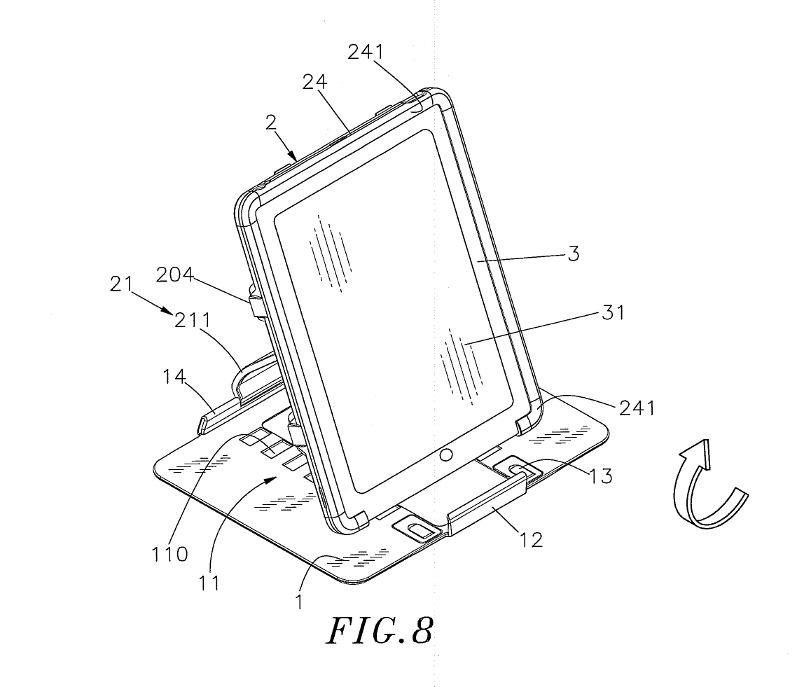

During application, by means of biasing the connection plate member 211 of the connection device 21 relative to the knuckles 140 of the coupling structure 14, the holder frame unit 2 can be opened from the base frame unit 1 (see FIG. 5). Thereafter, the sliding plate member 212 can be movable out of the sliding way 2110 of the connection plate member 211 and positioned in the desired position by means of selectively engaging the springy retaining portion 2121 in one of the positioning grooves 2112 (see FIG. 5 and FIG. 6). Further, subject to the coupling arrangement between the hollow shaft 22 at the flat holder panel 20 and the swivel connector 213 of the connection device 21, the flat holder panel 20 can be rotated to the desired angle relative to the base frame unit 1. Further, subject to the coupling arrangement between the pivot pins 2123 of the sliding plate member 212 and the pivot holes 2131 of the swivel connector 213, the flat holder panel 20 can be biased relative to the connection device 21 to let the positioning blocks 204 be selectively positioned in the locating grooves 110 of the base panel 11 of the base frame unit 1 (see FIG. 8). Alternatively, the operative stop members 13 can be set in the operative position to support the flat holder panel 20 in a tilted position on the base panel 11 of the base frame unit 1 (see FIGS. 6 and 7).

Thus, the user can bias and rotate the holder frame unit 2 relative to the base frame unit 1 to hold the accommodated tablet PC 3 in any desired angle and position, facilitating using the tablet PC 3.

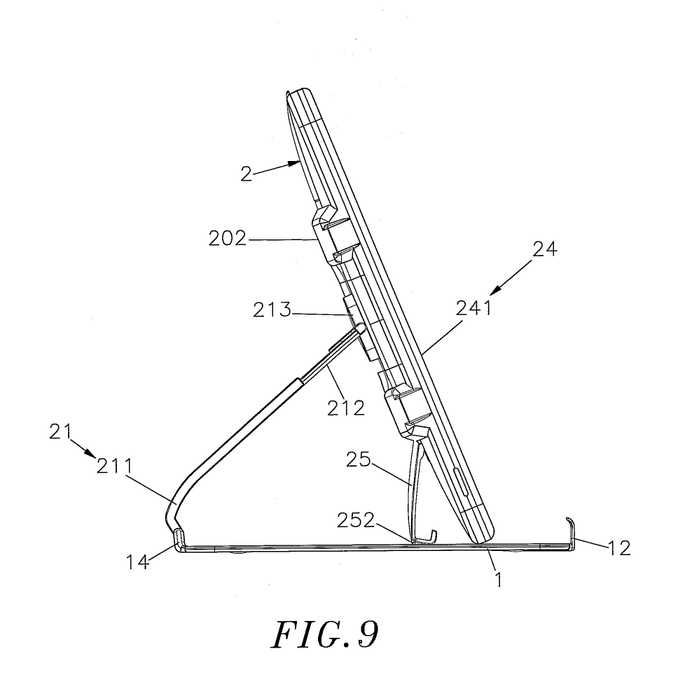

Referring to FIG. 9 and FIGS. 7 and 8 again, after opening the holder frame unit 2 from the base frame unit 1 and biasing the flat holder panel 20 relative to the connection device 21 to the desired angle, the flat holder panel 20 can be held in the horizontal operating mode (where the opposing long sides of the rectangular flat older panel 20 are kept in parallel to the base frame unit 1), and then selectively positioned in the locating grooves 110 of the base panel 11 of the base frame unit 1 or stopped at the operative stop members 13 in a tilted position on the base panel 11 of the base frame unit 1 (see FIG. 7). Further, subject to the coupling arrangement between the hollow shaft 22 at the flat holder panel 20 and the swivel connector 213 of the connection device 21, the flat holder panel 20 can be rotated through 90° angle from the horizontal operating mode (where the opposing long sides of the rectangular flat older panel 20 are kept in parallel to the base frame unit 1) to the vertical operating mode (where the opposing short, sides of the rectangular flat older panel 20 are kept in parallel to the base frame unit 1) and then selectively positioned in the locating grooves 110 of the base panel 11 of the base frame unit 1 (see FIG. 8) or stopped at the operative stop members 13 in a tilted position on the base panel 11 of the base frame unit 1. When the flat older panel 20 is supported on the base panel 11 of the base frame unit 1 in a tilted position, the side cover 25 can be turned outwardly from the flat holder panel 20 to selectively position the locating blocks 252 in the locating grooves 110 of the base panel 11, thereby supporting the flat older panel 20 firmly in the adjusted tilted position.

The above description is simply an example of the invention for easy understanding of the spirit and scope of the invention but not intended as limitations. In general, the invention provides a tablet PC supplementary device comprising: a base frame unit 1 comprising a flat base panel 11 having a springy hook flange 12 and a coupling structure 14 respectively located on front and rear sides thereof; a holder frame unit 2 comprising a flat holder panel 20 defining therein an accommodation open chamber 201 for accommodating a tablet PC 3, a connecting device 21 pivotally connecting the flat holder panel 20 to the coupling structure 14 of the base frame unit 1 and a swivel connector 213 rotatably connecting the flat holder panel 20 to the connecting device 21. Thus, the loaded tablet PC 3 can be biased and rotated with the flat holder panel 20 relative to the base frame unit 1 and then supported on the flat base panel 11 in a tilted position. When not in use, the base frame unit 1 can be closed on the holder frame unit 2 to keep the tablet PC 3 in between the base frame unit 1 and the holder frame unit 2, conveniently for carrying and storage.

In actual application, the tablet PC supplementary device of the invention has advantages as follows:
1. Subject to the coupling arrangement between the connection plate member 211 of the connection device 21 and the coupling structure 14 of the flat base panel 11, the coupling arrangement between the hollow shaft 22 at the flat holder panel 20 and the swivel connector 213 of the connection device 21 and the coupling arrangement between the pivot pins 2123 of the sliding plate member 212 and the pivot holes 2131 of the swivel connector 213, the tablet PC 3 that is accommodated in the flat holder panel 20 can be adjusted horizontally and vertically to the desired tilted position for operation conveniently.
2. The tablet PC 3 is accommodated in the flat holder panel 20. When not in use, the base frame unit 1 can be closed on the holder frame unit 2 to keep the tablet PC 3 in between the base frame unit 1 and the holder frame unit 2, conveniently for carrying and storage and preventing any accidental scratching or damage.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A tablet PC supplementary device, comprising:
a base frame unit comprising a flat base panel, said flat base panel having a springy hook flange located on a front side thereof, a coupling structure located on a rear side thereof and a plurality of locating means spaced on a top wall thereof between said springy hook flange and said coupling structure;
a holder frame unit comprising a flat holder panel defining therein an accommodation open chamber for accommodating a tablet PC, a retractable connecting device pivotally connecting said flat holder panel to said coupling structure of said base frame unit, and pivotally and rotatably connecting said flat holder panel to said connecting device, and positioning means located on one side of said flat holder panel for selectively positioning in said locating means to support said flat holder panel on said flat base panel in a tilted position.

2. The tablet PC supplementary device as claimed in claim 1, wherein said locating means comprises two series of locating grooves arranged in parallel between said springy hook flange and said coupling structure; said positioning means comprises two positioning blocks protruded from one side of said flat holder panel selectively positioning in said two series of locating grooves.

3. The tablet PC supplementary device as claimed in claim 1, wherein said flat base panel comprises two stop members hinged to the top wall thereof at two opposite lateral sides relative to said springy hook flange for stopping said flat holder panel on said flat base panel in a tilted position.

4. The tablet PC supplementary device as claimed in claim 1, wherein said coupling structure of said flat base panel comprises a plurality of knuckles; said retractable connecting device comprises a connection plate member pivotally connected to said knuckles of said coupling structure by a pivot pin.

5. The tablet PC supplementary device as claimed in claim 1, wherein said connection device comprises a connection plate member pivotally connected to said coupling structure of said flat base panel, said connection plate defining therein a sliding way, a sliding plate member coupled to and movable in and out of said sliding way of said connection plate member, and a swivel connector pivotally connected to one end of said sliding plate member outside said connection plate member, a hollow shaft fixedly located on said flat holder panel, and a retaining member fastened to said swivel connector to rotatably secure said swivel connector to said hollow shaft.

6. The tablet PC supplementary device as claimed in claim 1, wherein said holder frame unit further comprises two sleeves fixedly located on said flat holder panel in a parallel manner, each said sleeve having an opening on one end thereof, and a handle coupled to and slidably movable in and out of the opening of each said sleeve.

7. The tablet PC supplementary device as claimed in claim 6, wherein said handle is a substantially U-shaped frame bar, having two parallel arms respectively slidably inserted through the openings of said sleeves into said sleeves.

8. The tablet PC supplementary device as claimed in claim 7, wherein each said arm of said handle has a locating end portion located on a distal end thereof and stoppable at the stop flange in the opening of the associating sleeve; each said sleeve comprises a stop flange disposed around the opening thereof for stopping the locating end portion of the associating arm of said handle in the respective sleeve.

9. The tablet PC supplementary device as claimed in claim 1, wherein said holder frame unit further comprises a packing rim packed on said flat holder panel around said accommodation open chamber, said packing rim having a retaining flange extending around said accommodation open chamber, and a side cover pivotally connected to said flat holder panel, said side cover having two locating blocks bilaterally disposed at a rear side thereof and selectively positionable in said locating means of said flat base panel.

10. The tablet PC supplementary device as claimed in claim 9, wherein said packing ring has the shape of a rectangular open frame.

11. The tablet PC supplementary device as claimed in claim 9, wherein said packing ring has the shape of a [symbol] -shaped open frame.

12. The tablet PC supplementary device as claimed in claim 9, wherein said packing ring has the shape of a U-shaped open frame.

13. The tablet PC supplementary device as claimed in claim 9, wherein said flat holder panel comprises two coupling holes bilaterally disposed near one side thereof; said side cover comprises two coupling portions bilaterally disposed at a front side thereof and respectively pivotally coupled to the coupling holes of said flat holder panel.

14. The tablet PC supplementary device as claimed in claim 1, wherein said holder frame unit further comprises an inner covering covered on said flat holder panel over said accommodation chamber.
